(19) United States
(12) Patent Application Publication
(10) Pub. No.: US 2014/0166345 A1
(43) Pub. Date: Jun. 19, 2014

(54) TRANSPARENT CONDUCTING GLASS AND METHOD OF MANUFACTURING SAME

(71) Applicant: HON HAI PRECISION INDUSTRY CO., LTD., New Taipei (TW)

(72) Inventor: SEI-PING LOUH, New Taipei (TW)

(73) Assignee: HON HAI PRECISION INDUSTRY CO., LTD., New Taipei (TW)

(21) Appl. No.: 13/771,368

(22) Filed: Feb. 20, 2013

(30) Foreign Application Priority Data
Dec. 17, 2012 (TW) 101147762

(51) Int. Cl. H05K 1/03; H05K 3/10

(52) U.S. Cl. CPC H05K 1/0306; H05K 3/107
USPC 174/255; 427/97.8; 216/18; 427/540

(57) ABSTRACT

A transparent conducting glass includes a glass substrate and a conducting glue. The glass substrate includes a first surface and a second surface opposite to the first surface, and defines a number of strip recesses on the first surface according to a circuit route. The conducting glue is infilled into the strip recesses and forms a circuit for transmitting signals.

### BACKGROUND

1. Technical Field

The present disclosure relates to glass, and particularly, to a transparent conducting glass and a method of manufacturing the transparent conducting glass.

2. Description of Related Art

Transparent conducting glass includes a glass substrate and a conducting layer covering the glass substrate. The glass substrate is generally cut from common glass. As there are natural cracks in the surface of the glass substrate, when an external force is exerted on the transparent conducting glass, the transparent conducting glass will be easily damaged.

Therefore, it is desirable to provide a transparent conducting glass and a method of manufacturing the transparent conducting glass, which can overcome the limitations described.

### BRIEF DESCRIPTION OF THE DRAWINGS

FIG. 1 is a cross-sectional view of a transparent conducting glass in accordance with an exemplary embodiment.

FIG. 2 is a flow chart of a method of manufacturing the transparent conducting glass of FIG. 1 in accordance with another exemplary embodiment.

### DETAILED DESCRIPTION

Embodiments of the disclosure will be described with reference to the drawings.

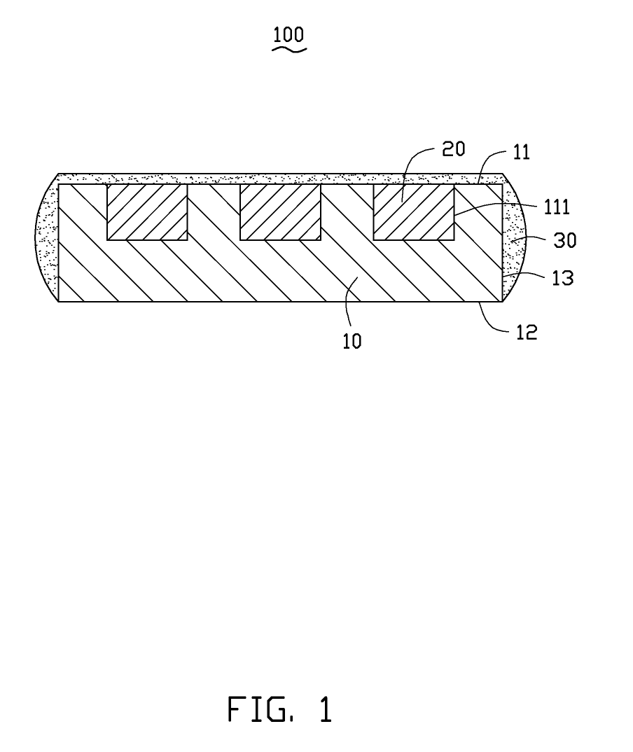

FIG. 1 shows a transparent conducting glass 100 according to an exemplary embodiment. The transparent conducting glass 100 includes a glass substrate 10, a conducting glue 20, and a transmission enhanced layer 30.

The glass substrate 10 is cut from common glass. The glass substrate 10 includes a first surface 11, such as an upper surface as shown in FIG. 1, a second surface 12, such as a lower surface as shown in FIG. 1, and a third surface 13, such as a side surface as shown in FIG. 1. The second surface 12 is opposite to the first surface 11, and the third surface 13 connects between the first surface 11 and the second surface 12. The glass substrate 10 defines a number of strip recesses 111 on the first surface 11 according to a circuit route which is predesigned. In other embodiments, the strip recesses 111 can be formed on the first surface 11, or in both the first surface 11 and the second surface 12.

A width of the strip recesses 111 (i.e., a length measured along a direction perpendicular to an extending direction of the strip recesses 111) is greater than about 100 nm and less than about 500 nm. If the width of the strip recesses 111 is less than about 100 nm, improvement of toughness, shock resistance, and hardness of the glass substrate 10 may not be achieved. If the width of the strip recesses 111 is greater than about 500 nm, toughness, shock resistance, and hardness of the glass substrate 10 may be decreased.

The conducting glue 20 is one kind of gule doped with conducting particles, such as, sliver or carbon nanotube. In this embodiment, the gule is made of the polymethyl methacrylate or the epoxy resin. The refractive index of the conducting glue 20 is substantially equal to the refractive index of the glass substrate 10. The conducting glue 20 is infilled in the strip recesses 111, and forms a circuit. The level of the conducting glue 20 is coplanar with the first surface 11 of the glass substrate 10. The conducting glue 20 solidifies or is solidified after the conducting glue 20 is coplanar with the first surface 11.

The transmission enhanced layer 30 is made of the tetraethylorthosilicate. The transmission enhanced layer 30 covers on the first surface 11 and the conducting glue 20. The transmission enhanced layer 30 is configured for increasing transmission of the transparent conducting glass 100. The transmission enhanced layer 30 further covers on the third surface 13 of the glass substrate 10, and the transmission enhanced layer 30 is infilled into cracks which are formed on the third surface 13 when the glass substrate 10 is cut.

In use, the first surface 11 of the transparent conducting glass 100 faces the outside. When an external force is applied to the transparent conducting glass 100, the transparent conducting glass 100 is stronger as the first surface 11 is strengthened. Therefore, the transparent conducting glass 100 acts to protect anything or any person inside the transparent conducting glass 100. Furthermore, as the conducting glue 20 filling in the strip recesses 111 is one kind of gule doped with conducting particles, and signals can be transmitted thought the conducting glue 20.

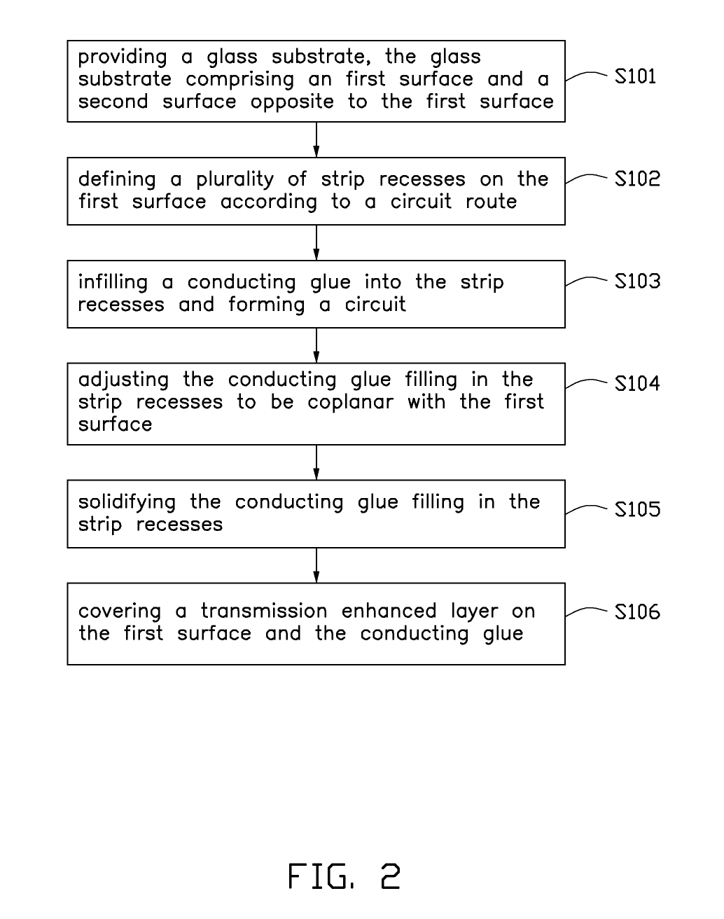

FIG. 2 shows a method of manufacturing the transparent conducting glass 100, according to an exemplary embodiment. The method includes steps of S101-S106.

S101: a glass substrate 10 is provided, the glass substrate 10 includes an first surface 11, a second surface 12 opposite to the first surface 11, and a third surface 13 connected between the first surface 11 and the second surface 12.

S102: the glass substrate 10 defines a number of strip recesses 111 on the first surface 11 according to a circuit route which is predesigned. In this embodiment, the strip recesses 111 are defined by chemical etching, high temperature melting, or electrical discharge machining process.

S103: the conducting glue 20 is infilled into the strip recesses 111 of the first surface 11 and forms a circuit. The conducting glue 20 is one kind of gule doped with conducting particles, such as, sliver or carbon nanotube. In this embodiment, the gule is made of the polymethyl methacrylate or the epoxy resin. The refractive index of the conducting glue 20 is substantially equal to the refractive index of the glass substrate 10. In this embodiment, the conducting glue 20 is stored in a number of evenly spaced sprayers, the sprayers move along the circuit route, and the conducting glue 20 sprayed from the sprayers is infilled into the strip recesses 111.

S104: the level of the conducting glue 20 filling in the strip recesses 111 is adjusted to be coplanar with the first surface 11.

S105: the conducting glue 20 filling the strip recesses 111 and covering the third surface 13 solidifies or is solidified.

S106: a transmission enhanced layer 30 covers on the first surface 11 and the conducting glue 20. The transmission enhanced layer 30 is made of the tetraethylorthosilicate, and configured for increasing transmission of the transparent conducting glass 100. The transmission enhanced layer 30 further covers on the third surface 13 of the glass substrate 10, and the transmission enhanced layer 30 is infilled into cracks which are formed on the third surface 13 when the glass substrate 10 is cut.

The glass substrate 10 defines a number of strip recesses 111, and the conducting glue 20 is infilled into the strip recesses 111, therefore any fissures on the first surface 11 are also infilled and thus canceled, and the strength of the transparent conducting glass 100 is increased. Furthermore, the conducting glue 20 filling in the strip recesses 111 severs as the circuit, and signals can be transmitted thought the conducting glue 20.

Particular embodiments are shown and described by way of illustration only. The principles and the features of the present disclosure may be employed in various and numerous embodiments thereof without departing from the scope of the disclosure as claimed. The above-described embodiments illustrate the scope of the disclosure but do not restrict the scope of the disclosure.

1. A transparent conducting glass, comprising:
a glass substrate comprising a first surface and a second surface opposite to the first surface, the glass substrate defining a plurality of strip recesses on the first surface according to a circuit route; and
a conducting glue infilled into the strip recesses and forming a circuit for transmitting signals;
wherein the refractive index of the conducting glue is equal to the refractive index of the glass substrate.

2. The transparent conducting glass of claim 1, further comprising a transmission enhanced layer covering on the first surface and the conducting glue.

3. (canceled)

4. The transparent conducting glass of claim 1, wherein the conducting glue is one kind of gule doped with conducting particles.

5. The transparent conducting glass of claim 1, wherein the level of the conducting glue is coplanar with the first surface of the glass substrate.

6-10. (canceled)

11. The transparent conducting glass of claim 1, wherein a width of the strip recesses is greater than about 100 nm and less than about 500 nm.
